(19) United States
(12) Patent Application Publication
(10) Pub. No.: US 2005/0048766 A1
(43) Pub. Date: Mar. 3, 2005

(54) METHOD FOR FABRICATING A CONDUCTIVE PLUG IN INTEGRATED CIRCUIT

(76) Inventors: Wen-Chieh Wu, Tao-Yuan City (TW); Yi-Nan Chen, Taipei City (TW); Chun-Yi Wu, Taipei City (TW)

Correspondence Address: (NAIPC) NORTH AMERICA INTERNATIONAL PATENT OFFICE, P.O. BOX 506, MERRIFIELD, VA, 22116, US

(21) Appl. No.: 10/605,007

(22) Filed: Aug. 31, 2003

(51) Int. Cl. H01L 21/4763; H01L 21/22; H01L 21/38; H01L 21/44

(52) U.S. Cl. 438/629; 438/558; 438/657

(57) ABSTRACT

A method for fabricating a conductive plug device is disclosed. A semiconductor substrate having a diffusion region thereon is provided. A dielectric layer is deposited over the semiconductor substrate. An opening is formed in the dielectric layer to expose a portion of the diffusion region. An un-doped CVD silicon layer is deposited on interior walls of the opening. A pure CVD phosphorus layer is in-situ deposited on the un-doped CVD silicon layer. The pure CVD phosphorus layer thereafter diffuses into the subjacent un-doped CVD silicon layer to form a doped silicon layer. Subsequently, a second un-doped CVD silicon layer is in-situ deposited on the doped silicon layer.

### BACKGROUND OF INVENTION

1. Field of the Invention

The present invention relates to a method for fabricating a conductive plug in integrated circuits. More particularly, the present invention relates to a method for fabricating a doped polycrystalline silicon plug with stable and low resistance by using ramp-type in-situ doping technique.

2. Description of the Prior Art

High-density integrated circuits are typically formed with a multi-level interconnect structure including two or more levels of metallization layers for electrically interconnecting various components in the integrated circuits. A multi-level interconnect structure includes a base layer of metallization layer which is electrically connected to the source/drain regions of the MOS transistor devices, and at least a second layer of metallization layer which is separated from the base layer of metallization layer by an inter-metal dielectric (IMD) layer, with the second layer of metallization layer being electrically connected to the base layer of metallization layer through a via plug formed in the IMD layer. It is to be noted that, in the literature of IC fabrication, the term “contact plug” customarily refers to a conductive plug that interconnects an upper level of metallization layer and a conductive part in the substrate, such as a source/drain region of a MOS transistor, whereas the term “via plug” refers to a conductive plug that is interconnected between an upper level of metallization layer and a lower level of metallization layer. Hereinafter, either “contact plug” or “via plug” is collectively referred to as “conductive plug”. Tungsten metal plugs and doped polysilicon plugs are known in the art, in which the doped polysilicon plugs are widely used in the fabrication of dynamic random access memory (DRAM) devices because they are cheaper than tungsten metal plugs.

A conventional method for fabricating a polysilicon plug comprises depositing an insulating layer or a dielectric layer on a provided substrate, performing a lithographic and etching process to form an opening within the insulating layer to expose a part of the substrate, and then depositing a doped polysilicon layer in the opening and on the insulating layer using chemical vapor deposition (CVD) technique, usually followed by chemical mechanical polishing to remove the polysilicon layer outside the opening. Typically, the CVD polysilicon layer is in-situ doped with dopants such as phosphor. It is known that the doped polysilicon may be formed by low-pressure chemical vapor deposition (LPCVD) with silane (SiH₄) and phosphine (PH₃) as reaction gases, where phosphine gas serves as an in-situ dopant source. A doped amorphous polysilicon layer is first deposited on the substrate. At a temperature of about 500˜600° C., the amorphous polysilicon layer is gradually transformed into polysilicon structure.

Please refer to FIG. 1. FIG. 1 is a plot of flow rate vs. process time showing the flow rates of source gases including silane (SiH₄) and phosphine (PH₃) during an in-situ doping polysilicon CVD process according to the prior art. As shown in FIG. 1, according to the prior art method, during the in-situ doping polysilicon CVD process, the ratio of the flow rate of silane to the flow rate of phosphine is maintained at a fixed value. The flow rates of the two source gases are constant. Typically, the flow rate of silane is larger than the flow rate of dopant source gas phosphine during the in-situ doping polysilicon CVD process.

Theoretically, the resultant doped polysilicon has a doping pattern that phosphine atoms are randomly and evenly distributed through the entire thickness of the doped polysilicon layer or conductive plug. However, it is found that in most cases the doping pattern of phosphine varies through the thickness of the resultant doped polysilicon layer, especially in the conductive plug. For example, in some worse cases, the doping concentration of phosphine is higher at the bottom of the conductive plug than the doping concentration at its higher portions. It is surmised that the difference between the atomic weights of phosphor and silicon might be a main factor causing the varying concentration distribution. Besides, the prior art method for making the conductive plug cannot control the concentration distribution thereof. It is often desirable to control the doping concentration of a conductive plug thereby obtaining a desired junction resistance.

### SUMMARY OF INVENTION

Accordingly, it is the primary objective of the present invention to provide an improved method for fabricating a conductive plug having stable and controllable plug resistance.

According to the claimed invention, a method for making a conductive plug is disclosed. Briefly, a substrate having thereon a diffusion region is first provided. A dielectric layer is deposited on the substrate. An opening is formed in the dielectric layer, the opening exposing a part of the diffusion region of the substrate. A first non-doped silicon layer is then deposited in the opening. A first transient pure phosphor film is in-situ deposited on the first non-doped silicon layer in the opening, wherein phosphor atoms of the first transient pure phosphor film diffuse into the first non-doped silicon layer in no time to form a first doped silicon layer. A second non-doped silicon layer is thereafter in-situ deposited on the first doped silicon layer in the opening.

From one aspect of the present invention, a method for making a conductive plug involving metal interconnection is disclosed. A substrate having thereon a first metal is provided. A dielectric layer is then deposited on the substrate. An opening is formed in the dielectric layer. The opening exposes a part of the first metal on the substrate. A first non-doped silicon layer is deposited in the opening. A first transient pure phosphor film is in-situ deposited on the first non-doped silicon layer in the opening, wherein phosphor atoms of the first transient pure phosphor film diffuse into the first non-doped silicon layer in no time to form a first doped silicon layer. A second non-doped silicon layer is in-situ deposited on the first doped silicon layer in the opening.

From another aspect of the present invention, a method for making a conductive plug disclosed. A semiconductor substrate having thereon a dielectric layer is prepared. An opening is formed in the dielectric layer. The semiconductor substrate is then situated in a CVD vacuum chamber. Silane gas and phosphine gas are alternately introduced into the CVD vacuum chamber and undergoing a chemical vapor deposition reaction to deposit a plurality of pure silicon layers and pure phosphor films on the dielectric layer and also in the opening, wherein each of the pure phosphor films is interposed between two of the pure silicon layers, and phosphor atoms of the pure phosphor films diffuse into adjoining pure silicon layers.

Other objects, advantages, and novel features of the claimed invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a plot of flow rate vs. process time showing the flow rates of source gases including silane (SiH₄) and phosphine (PH₃) during an in-situ doping polysilicon CVD process according to the prior art method;

FIG. 2 is a schematic cross-sectional diagram showing the alternately in-situ doped conductive plug according to the preferred embodiment of the present invention;

FIG. 3 is a plot of flow rate vs. process time showing the flow rates of source gases including silane (SiH₄) and phosphine (PH₃) during the layer-by-layer in-situ doping CVD process according to the present invention; and

FIG. 4 to FIG. 10 are schematic cross-sectional diagrams illustrating the fabrication process of the layer-by-layer doped conductive plug of FIG. 2 according to the preferred embodiment of this invention.

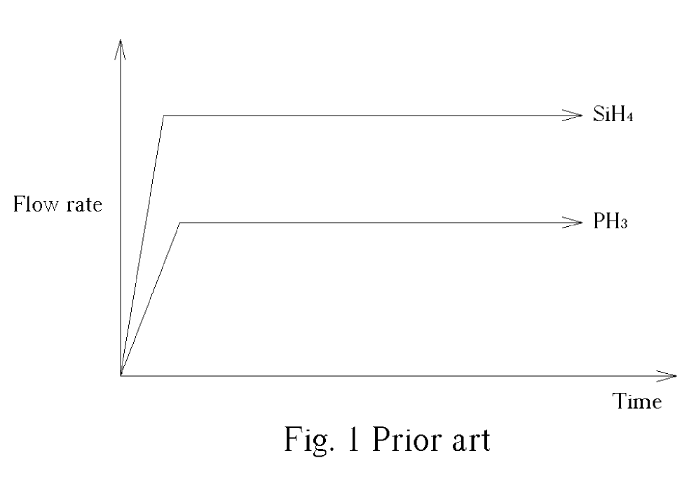

### DETAILED DESCRIPTION

The present invention pertains to a conductive plug structure such as a contact plug or a via plug, and the fabrication method thereof. More specifically, the present invention discloses a method for fabricating a doped polycrystalline silicon plug with stable and low resistance by using ramp-type in-situ doping technique. In accordance with the present invention, the conductive plug is alternately in-situ doped layer by layer.

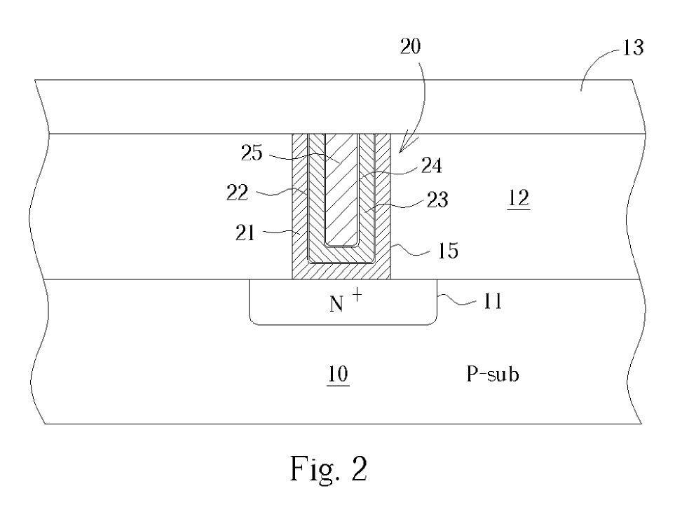

Please refer to FIG. 2. FIG. 2 is a schematic cross-sectional diagram showing the alternately in-situ doped conductive plug according to the preferred embodiment of the present invention. As shown in FIG. 2, in this embodiment, the conductive plug 20 is used to electrically connect a N⁺ diffusion region 11 of a P type semiconductor substrate 10 with the first level metal interconnection 13. The N⁺ diffusion region 11 may be a source/drain region of a MOS transistor device. It is understood that the types of semiconductor regions are chosen solely for illustration, and persons having ordinary skill in the art would recognize other alternatives, variations, and modifications. In this preferred embodiment, the conductive plug 20 comprises an outer polysilicon layer 21, an intermediate polysilicon layer 23, and an inner polysilicon layer 25. A first CVD phosphor dopant diffusion layer 22 is sandwiched between the outer polysilicon layer 21 and the intermediate polysilicon layer 23.

The conductive plug structure is formed according to layer-by-layer in-situ doping technique of the present invention. In effect, a pure CVD phosphor layer is not physically seen in the polysilicon plug structure, because the CVD phosphor atoms diffuse into the pure polysilicon layer once the phosphor atoms deposit thereon. More specifically, a first peak doping concentration of phosphor can be found at the interface between the adjoining outer polysilicon layer 21 and the intermediate polysilicon layer 23. A concentration gradient is observed at both sides of the interface between the outer polysilicon layer 21 and the intermediate polysilicon layer 23 due to diffusion. A second CVD phosphor dopant diffusion layer 24 is sandwiched between the outer polysilicon layer 23 and the intermediate polysilicon layer 25. Likewise, a second peak doping concentration of phosphor is found at the interface between the intermediate polysilicon layer 23 and inner polysilicon layer 25. A diffusion gradient is found at both sides of the interface between the intermediate polysilicon layer 23 and inner polysilicon layer 25. It is noted that the doping concentration in the intermediate polysilicon layer 23 may be higher than that either of the inner polysilicon layer 25 or outer polysilicon layer 21 because both the first CVD phosphor dopant diffusion layer 22 and the second CVD phosphor dopant diffusion layer 24 contribute to the doping concentration of the intermediate polysilicon layer 23.

The above-described plug structure is only an exemplary preferred embodiment, and persons having ordinary skill in the art would recognize other alternatives, variations, and modifications. For example, the first CVD phosphor dopant diffusion layer 22 and the second CVD phosphor dopant diffusion layer 24 may have different phosphor concentrations and are both adjustable depending on process demands. In other cases, there may be third CVD phosphor dopant diffusion layer, fourth CVD phosphor dopant diffusion layer, nth CVD phosphor dopant diffusion layer, and so on. In another preferred embodiment of the present invention, only a layer of CVD phosphor dopant diffusion is presented.

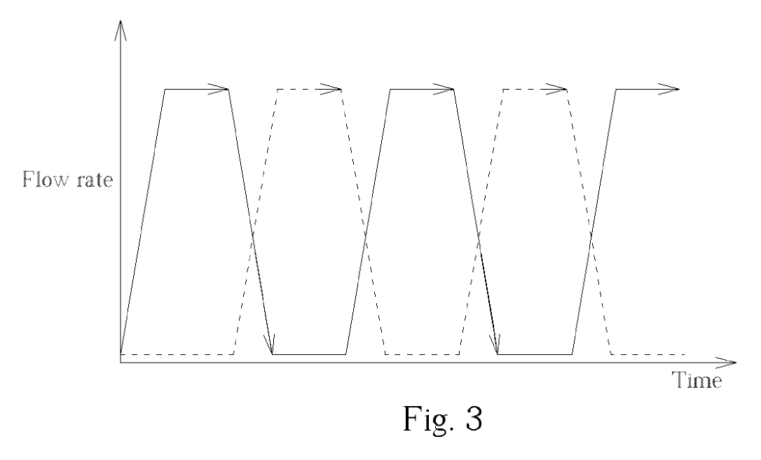

Please refer to FIG. 3. FIG. 3 is a plot of flow rate vs. process time showing the flow rates of source gases including silane (SiH₄) and phosphine (PH₃) during the layer-by-layer in-situ doping CVD process according to the present invention. The layer-by-layer in-situ doping chemical vapor deposition process takes place in a conventional vacuum chamber (not shown). Two source gases are injected into the vacuum chamber during the process. The two source gases are industry-grade silane (SiH₄; indicated with bold line) and phosphine (PH₃; indicated with dash line). As shown in FIG. 3, the two source gases are alternately injected into the vacuum chamber. There are five stages (or cycles) shown in FIG. 3. In the first stage, only silane gas is injected into the vacuum to deposit a non-doped or pure amorphous silicon layer on the surface of a semiconductor substrate. In the following second stage, the silane gas is shut off, and the phosphine gas begins to flow into the vacuum thereby depositing a transient pure thin phosphor film on the previous-formed pure amorphous silicon layer. The phosphor atoms diffuse into the previous-formed pure amorphous silicon layer right away. In the third stage, the phosphine gas is shut off, and the silane gas is again injected into the vacuum to deposit a non-doped or pure amorphous silicon layer on the surface of the previous-formed amorphous silicon layer. Phosphor atoms diffuse back into the pure amorphous silicon layer formed in the third stage. Then, the following fourth and fifth stages repeat the same procedures, and so on, thereby forming a layer-by-layer doped conductive plug as set forth in FIG. 2. It is noted that the flow rates of the silane gas and the phosphine gas are not maintained constant as the prior art. Instead, the present invention utilizes ramp-type in-situ doping technique to form conductive plugs with controllable alternating doping profile.

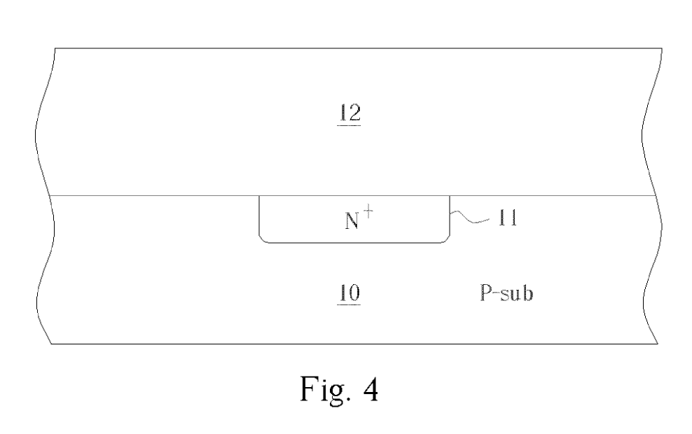

Please refer to FIG. 4 to FIG. 10. FIG. 4 to FIG. 10 are schematic cross-sectional diagrams illustrating the fabrication process of the layer-by-layer doped conductive plug of FIG. 2 according to the preferred embodiment of this invention. As shown in FIG. 4, a semiconductor substrate 10 such as a P type silicon substrate is provided. The semiconductor substrate 10 has an N type diffusion region 11. A dielectric layer 12 such as a silicon oxide layer, borophosphosilicate glass (BPSG), or phosphosilicate glass (PSG) is deposited on the surface of the substrate 10.

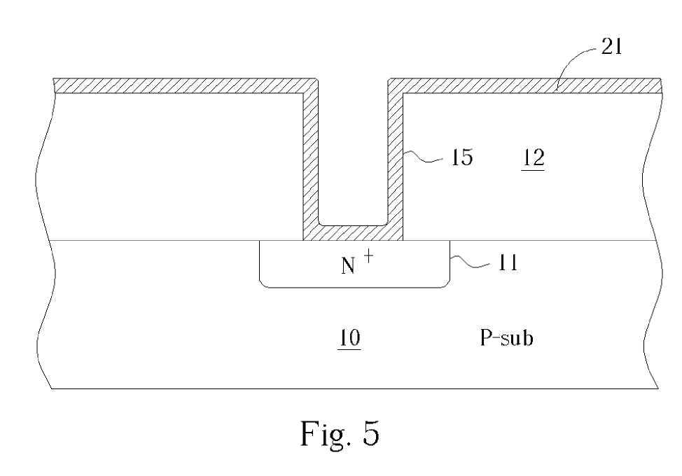

As shown in FIG. 5, a lithographic and etching process are carried out to etch a contact hole 15 in the dielectric layer 12, thereby exposing a part of the underlying N type diffusion region 11. The semiconductor substrate 10 is then transferred to a CVD vacuum chamber (not shown) to undergo a CVD process. First, silane gas is introduced into the vacuum chamber, and deposition takes place at low pressures to form a non-doped silicon layer 21 on sidewalls and bottom of the contact hole 15. Preferably, the non-doped silicon layer 21 has a thickness of 50˜300 angstroms, but not limited thereto.

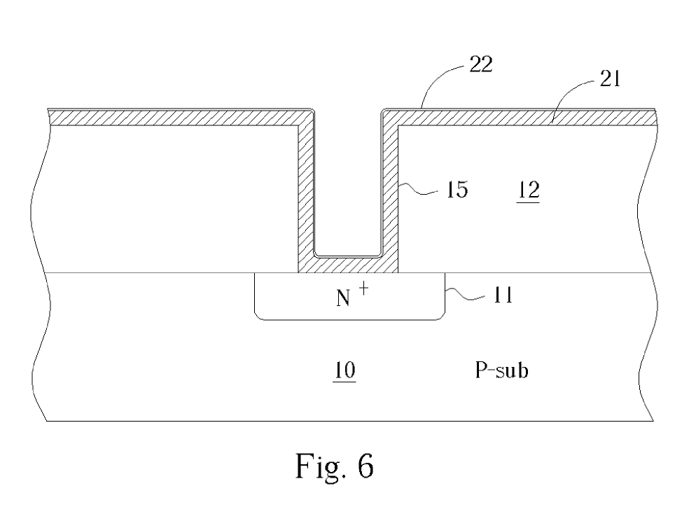

As shown in FIG. 6, the silane gas is shut off, meanwhile, the phosphine gas is introduced into the vacuum chamber. A first transient pure phosphor thin film 22 is deposited on the non-doped silicon layer 21. The chemical deposition of phosphor thin film can be expressed by the reaction equation as shown below. The phosphor atoms of the first transient pure phosphor thin film 22 diffuse into the silicon layer 21 in no time.
2PH_{3(g)}□2P₍ₛ₎+3H_{2(g)}

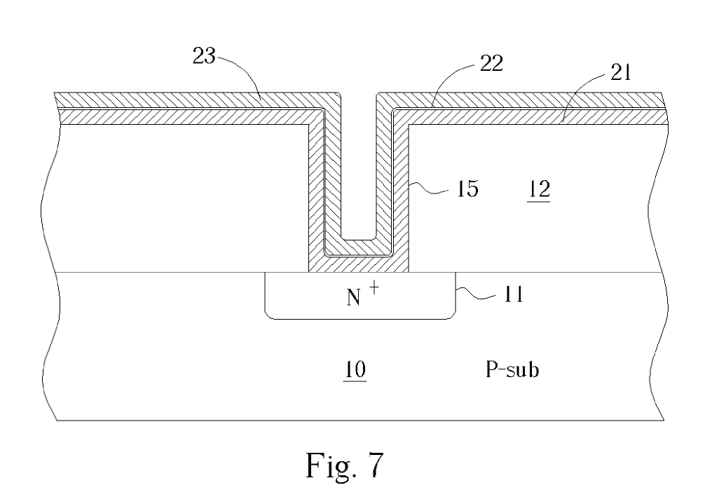

As shown in FIG. 7, the phosphine gas is shut off. Again, the silane gas is introduced into the vacuum chamber to deposit a non-doped silicon layer 23 over the first transient pure phosphor thin film 22. The phosphor atoms of the first transient pure phosphor thin film 22 diffuse into the silicon layers 21 and 23. At this phase, the highest doping concentration is at the interface between the silicon layers 21 and 23.

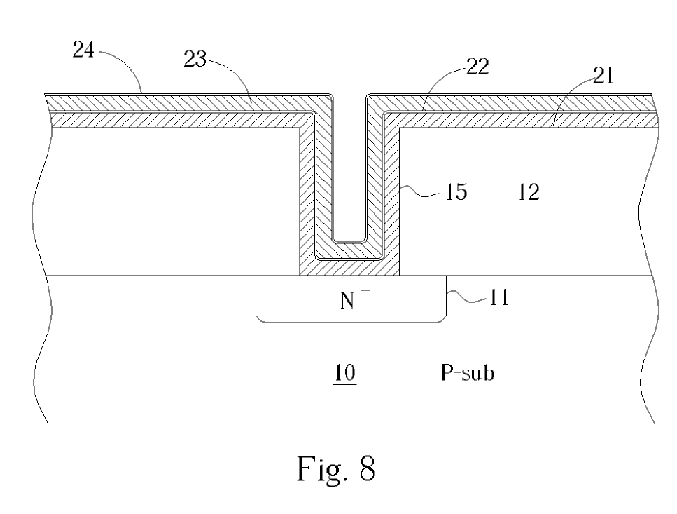

As shown in FIG. 8, the above-described cycle repeats. The silane gas is shut off is shut off. The phosphine gas is introduced into the vacuum chamber to deposit a second transient pure phosphor thin film 24 on the silicon layer 23. The phosphor atoms of the second transient pure phosphor thin film 24 diffuse into the silicon layer 23 in no time.

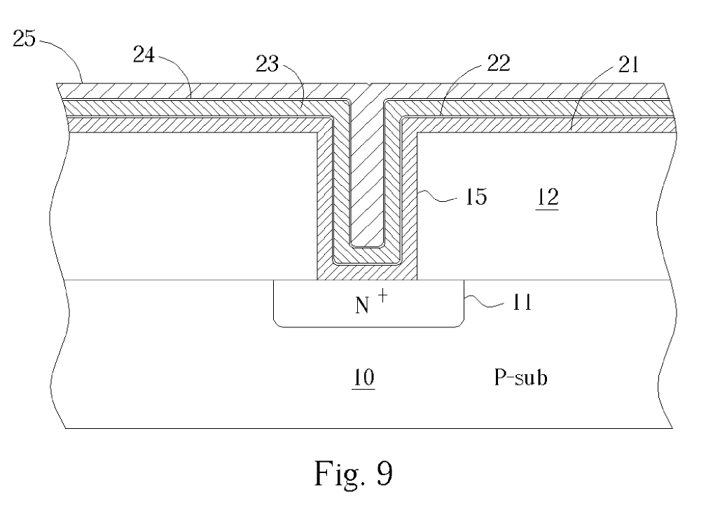

As shown in FIG. 9, the phosphine gas is shut off. The silane gas is introduced into the vacuum chamber to deposit a non-doped silicon layer 25 over the second transient pure phosphor thin film 24. The silicon layer 25 fills the contact hole 15. The phosphor atoms of the second transient pure phosphor thin film 22 diffuse into the silicon layers 23 and 25.

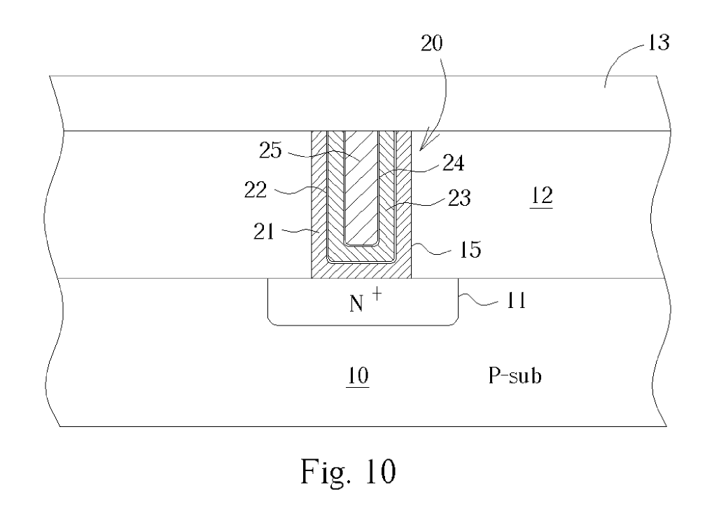

As shown in FIG. 10, a chemical mechanical polishing (CMP) is carried out to remove the silicon/phosphor stack outside the contact hole 15, thereby forming a layer-by-layer doped conductive plug 20 having a top surface that is coplanar with the dielectric layer 12. A first level of metal interconnection 13 is then formed on the plug 20 and on the dielectric layer 12. Before performing the CMP process, optionally, an annealing such as RTP can be carried out to transform amorphous silicon into polycrystalline silicon.

In another preferred embodiment of the present invention, only two pure silicon layers and one pure phosphor film is deposited in the contact hole. In still another preferred embodiment of the present invention, before depositing the first non-doped silicon layer 21, a preliminary doping may be carried out by depositing a pure phosphor film on the exposed bottom of the contact hole, thereby reducing the junction resistance between the conductive plug and the substrate diffusion regions.

Those skilled in the art will readily observe that numerous modifications and alterations of the present invention method may be made while retaining the teachings of the invention. Accordingly, the above disclosure should be construed as limited only by the metes and bounds of the appended claims.

1. A method for making a conductive plug, comprising:
providing a substrate having thereon a diffusion region;
depositing a dielectric layer on the substrate;
forming an opening in the dielectric layer, the opening exposing a part of the diffusion region of the substrate;
depositing a first non-doped silicon layer in the opening;
in-situ depositing a first transient pure phosphor film on the first non-doped silicon layer in the opening, wherein phosphor atoms of the first transient pure phosphor film diffuse into the first non-doped silicon layer in no time to form a first doped silicon layer; and
in-situ depositing a second non-doped silicon layer on the first doped silicon layer in the opening.

2. The method of claim 1 wherein after depositing the second non-doped silicon layer on the first doped silicon layer, the method further comprises the following steps:
in-situ depositing a second transient pure phosphor film on the second non-doped silicon layer in the opening,
wherein phosphor atoms of the second transient pure phosphor film diffuse into the second non-doped silicon layer in no time to form a second doped silicon layer; and
in-situ depositing a third non-doped silicon layer on the second doped silicon layer in the opening, wherein the third non-doped silicon layer fills the opening.

3. The method of claim 2 wherein after depositing the third non-doped silicon layer, the method further comprises the following step:
performing a chemical mechanical polishing (CMP) process to remove the silicon layers outside the opening, leaving the first doped silicon layer, the second doped silicon layer, and the third non-doped silicon layer in the opening to form a conductive plug.

4. The method of claim 1 wherein the diffusion region is a N+ diffusion region, and wherein the first and second transient pure phosphor films are both formed by CVD.

5. A method for making a conductive plug, comprising:
providing a substrate having thereon a first device;
depositing a dielectric layer on the substrate;
forming an opening in the dielectric layer, the opening exposing a part of the first device on the substrate;
depositing a first non-doped silicon layer in the opening;
in-situ depositing a first transient pure phosphor film on the first non-doped silicon layer in the opening, wherein phosphor atoms of the first transient pure phosphor film diffuse into the first non-doped silicon layer in no time to form a first doped silicon layer; and
in-situ depositing a second non-doped silicon layer on the first doped silicon layer in the opening.

6. The method of claim 5 wherein after depositing the second non-doped silicon layer on the first doped silicon layer, the method further comprises the following steps:
in-situ depositing a second transient pure phosphor film on the second non-doped silicon layer in the opening, wherein phosphor atoms of the second transient pure phosphor film diffuse into the second non-doped silicon layer in no time to form a second doped silicon layer; and
in-situ depositing a third non-doped silicon layer on the second doped silicon layer in the opening, wherein the third non-doped silicon layer fills the opening.

7. The method of claim 5 wherein the first device is a layer of metal interconnection.

8. A method for making a conductive plug, comprising:
providing a semiconductor substrate having thereon a dielectric layer, wherein an opening is formed in the dielectric layer;
situating the semiconductor substrate in a CVD vacuum chamber; and
alternately introducing silane gas and phosphine gas into the CVD vacuum chamber and undergoing a chemical vapor deposition reaction to deposit a plurality of pure silicon layers and pure phosphor films on the dielectric layer and also in the opening, wherein each of the pure phosphor films is interposed between two of the pure silicon layers, and phosphor atoms of the pure phosphor films diffuse into adjoining pure silicon layers.
